(19) United States
(12) Patent Application Publication
(10) Pub. No.: US 2026/0136501 A1
(43) Pub. Date: May 14, 2026

(54) HEAT SINKS HAVING AN EMBEDDED THREE-DIMENSIONAL PULSATING HEAT PIPE AND ELECTRIC VERTICAL TAKE-OFF AND LANDING VEHICLES INCORPORATING THE SAME

(71) Applicants: Toyota Motor Engineering & Manufacturing North America, Inc., Plano, TX (US); CALYOS SA, Charleroi (BE)

(72) Inventors: Vincent Dupont, Auderghem (BE); Shailesh N. Joshi, Ann Arbor, MI (US); Danny J. Lohan, West Bloomfield, MI (US)

(73) Assignees: Toyota Motor Engineering & Manufacturing North America, Inc., Plano, TX (US); CALYOS SA, Charleroi (BE)

(21) Appl. No.: 18/947,953

(22) Filed: Nov. 14, 2024

(51) Int. Cl. H05K 7/20; B64C 29/00; B64D 27/34; B64D 33/08

(52) U.S. Cl. CPC H05K 7/2039; B64C 29/0025; B64D 27/34; B64D 33/08; H05K 7/20309; H05K 7/20318; H05K 7/20336

(57) ABSTRACT

In one embodiment, a heat sink includes an evaporator plate having a heat receiving surface and a cooling surface, a plurality of fins extending from the heat receiving surface, a condenser plate transverse from the plurality of fins such that a gap is defined between the evaporator plate and the condenser plate, and a pulsating heat pipe channel embedded within the evaporator plate, the plurality of fins, and the condenser plate.

### BACKGROUND

Thermal management of electric vertical take-off and landing aircraft (eVTOL) motors and their power electronic components is challenging because fully electric propulsion systems do not produce waste heat as exhaust air, making it difficult to remove heat. Further, the materials around the heat source prevent the heat from dissipating to the surroundings. The heat from heat generating components such as power electronic devices should be removed so that they are kept within the operational temperature range and prevent catastrophic failure due to overheating. Although a single-phase (i.e., water or oil) pumped loop that is commonly applied to automobiles is an efficient cooling method, it requires relatively large mass, a complicated system configuration, and periodical maintenance in general, which are not ideal for an eVTOL aircraft.

Because the heat source is located in the motor and has only a small area of less than a few cm², highly efficient heat spreading in the heat sink is important to keep the temperature of the heat generating component within the operational range. Conventionally, a heat sink is made by bulk metal with high thermal conductivity such as copper or aluminum. Despite inferior conductivity than copper, the latter is preferable in terms of weight, but bulk aluminum sink can still be a heavy item for vehicles like eVTOL, where weight reduction is important. As long as the heat conduction is responsible for the heat spreading of heat sink, the mass reduction and high thermal performance are conflicting requirements: achieving high thermal performance requires thick fins, which increase mass.

Accordingly, alternative heat sinks for applications such as eVTOL applications may be desired.

### BRIEF SUMMARY

In one embodiment, a heat sink includes an evaporator plate having a heat receiving surface and a cooling surface, a plurality of fins extending from the heat receiving surface, a condenser plate transverse from the plurality of fins such that a gap is defined between the evaporator plate and the condenser plate, and a pulsating heat pipe channel embedded within the evaporator plate, the plurality of fins, and the condenser plate.

In another embodiment, an electronic assembly includes an electronic device. The electronic assembly also includes a heat sink including an evaporator plate having a heat receiving surface and a cooling surface, wherein the electronic device is coupled to the heat receiving surface, a plurality of fins extending from the heat receiving surface, a condenser plate transverse from the plurality of fins such that a gap is defined between the evaporator plate and the condenser plate, and a pulsating heat pipe channel embedded within the evaporator plate, the plurality of fins, and the condenser plate.

In another embodiment, an electric vertical take-off and landing vehicle (eVTOL) includes a body, a propeller coupled to the body, an electric motor operable to rotate the propeller, and electronic device operable to control the electric motor. The eVTOL also includes a heat sink including an evaporator plate having a heat receiving surface and a cooling surface, wherein the electronic device is coupled to the heat receiving surface, a plurality of fins extending from the heat receiving surface, a condenser plate transverse from the plurality of fins such that a gap is defined between the evaporator plate and the condenser plate, and a pulsating heat pipe channel embedded within the evaporator plate, the plurality of fins, and the condenser plate.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a pulsating heat pipe system according to one or more embodiments described and illustrated herein.

FIG. 2 illustrates an example heat sink having an embedded PHP channel according to one or more embodiments described and illustrated herein.

FIG. 3 illustrates another example heat sink having an embedded PHP channel according to one or more embodiments described and illustrated herein.

FIG. 4A illustrates the embedded PHP channels of the heat sink illustrated in FIG. 3 according to one or more embodiments described and illustrated herein.

FIG. 4B illustrates embedded PHP channels of a heat sink designed to cool multiple hot spots according to one or more embodiments described and illustrated here.

FIG. 5 illustrates an electric motor of an eVTOL according to one or more embodiments described and illustrated herein.

FIG. 6 illustrates a graph of thermal conductance per unit mass versus air volume flow rate according for a heat sink with a PHP channel and a heat sink without a PHP channel.

FIG. 7 illustrates a graph of heat transfer coefficient versus heat input for a heat sink with a filled PHP channel, a heat sink with an unfilled PHP channel, and a heat sink without a PHP channel.

### DETAILED DESCRIPTION

Embodiments of the present disclosure improve the heat spreading effect of a heat sink for various applications, such as eVTOL power electronics, while reducing mass compared to the conventional heat sinks by embedding a three-dimensional pulsating heat pipe (PHP) inside it.

More particularly, embodiments of the present disclosure solve the above-mentioned drawbacks and conflicting situations of a heat sink made by a bulk metal by having a PHP perform the heat transport. A PHP, also known as an oscillating heat pipe, is a two-phase passive heat transfer device that includes a capillary tube or channel that is bent repeatedly between heating and cooling sections. A working fluid is charged into the PHP, typically at half of the PHP internal volume. The inner diameter of the tube or the hydraulic diameter of the channel should be small enough so that the working fluid in the PHP exists as a mixture of liquid slugs and vapor plugs even in a gravitational environment, including inclinations and vehicle accelerations, within the whole operating temperature range. The working fluid evaporates at the heating section (i.e., evaporator) and condenses at the cooling section (i.e., condenser) repeatedly, inducing an oscillating flow between the evaporator and the condenser. This self-excited oscillation of the slug/plug flow is responsible for the heat transfer between two sections.

In embodiments, 3D flow paths are created inside a finned heat sink, and fluid is charged inside it thanks to pinched filling tube, making a PHP embedded heat sink. Unlike conventional PHP devices, the PHP channels of the present disclosure are concentrated in the evaporator and spread to each fin. Not only is the heat spreading effect improved by the two-phase flow, but also, due to the presence of the PHP channels, the mass of the heat sink is reduced even though the fluid is charged because the fluid density is generally less than half of that of a material such as aluminum. The device is fully passive as the driving force of the fluid oscillation is not an external force such as a mechanical pump but a pressure difference between the evaporator and condenser, therefore it is as reliable as a conventional bulk metal sink. This working principal also enables the device to be less sensitive regarding position in which the heat sink is installed, unlike a thermosyphon which do not operate under top heated orientation and microgravity, respectively, which may be important for eVTOL applications. The thickness of the wall between evaporator channels is also optimized to allow a conductive local heat transfer directly to the fins. Thus, the enhanced heat sinks of the present disclosure have a degraded operating mode in case of PHP damage.

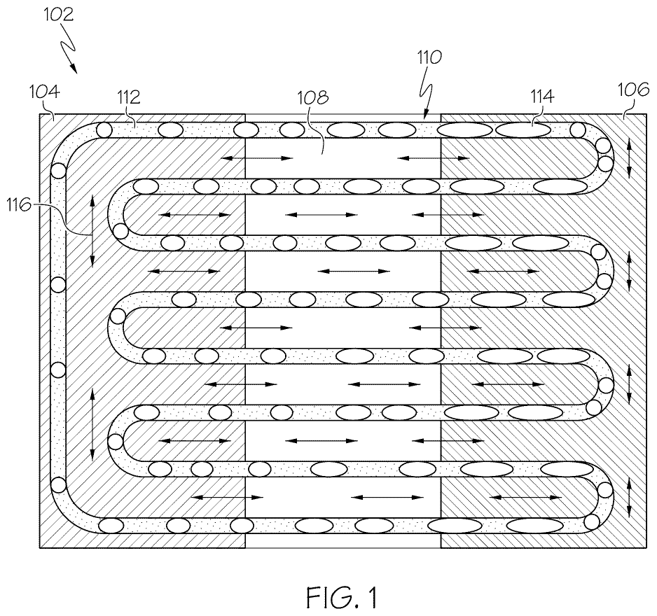

Referring now to FIG. 1, an example PHP system 102 is schematically illustrated. The PHP system 102 includes an evaporator section 106, a condenser section 104 and a central section 108 therebetween. The evaporator section 106 is thermally coupled to a heat generating component, such as an electronic device. The condenser section 104 is thermally coupled to a cooling component, such as a heat sink. The central section 108 that is located between the evaporator section 106 and the condenser section 104 may act as an adiabatic region where no heat is gained or lost.

The PHP system 102 further includes a closed-loop PHP channel 110 having a plurality of loops that traverse the evaporator section 106, the central section 108 and the condenser section 104 in a serpentine pattern. It should be understood that in other embodiments the PHP channel 110 may be an open loop. The PHP channel 110 is filled with a working fluid (e.g., water, glycol-based fluids, hydrocarbon-based fluids, refrigerant and the like) that provides a plurality of liquid slugs 112 and vapor plugs 114. The working fluid in the loops at the evaporator section 106 receives heat from the heat generating component while the working fluid in the loops at the condenser section 104 cools the working fluid. The temperature differential causes saturation pressure differential between the liquid slugs 112 and the vapor plugs 114 to oscillate back and forth between the evaporator section 106 and the condenser section 104, which transfers heat from the evaporator section 106 to the condenser section 104. This pulsating action of the working fluid within the PHP channel 110 cools the heat generating component.

In embodiments of the present disclosure, a single closed-loop and three-dimensional PHP channel passes through a plurality of fins of a heat sink. More particularly, embodiments of the present disclosure provide a heat sink that includes an evaporator plate that receives heat from a heat generating component and a condenser plate having a plurality of fins extending therethrough that provides a structure for cooling loops or passes to return to the evaporator plate through the plurality of fins. Unlike previous PHP systems, embodiments of the present disclosure provide a three-dimensional PHP channel that is routed through a plurality of fins rather than a single fin.

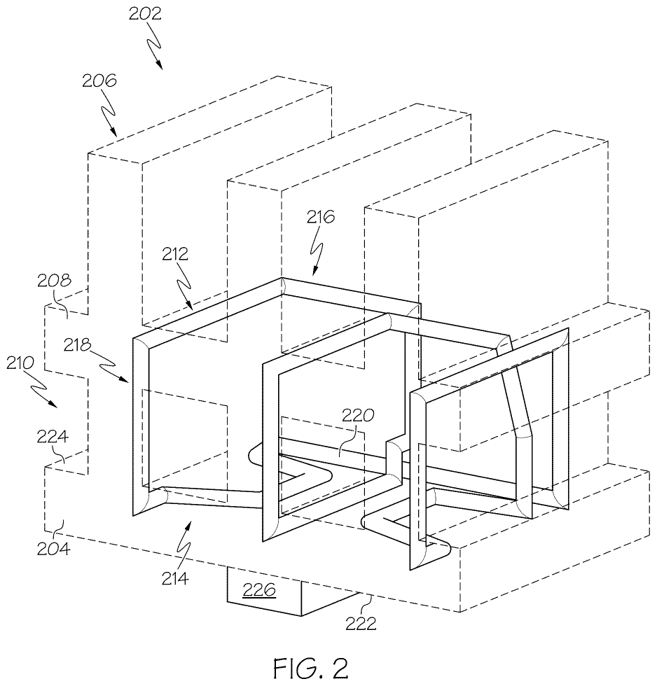

FIG. 2 illustrates a simple example of a heat sink incorporating the features of the present disclosure. The heat sink 202 generally includes an evaporator plate 204, a plurality of fins 206, a condenser plate 208, and a closed-loop PHP channel 212 that is filled with a working fluid having liquid slugs and vapor plugs. The evaporator plate 204, the plurality of fins 206 and the condenser plate 208 are shown as dashed lines to show the PHP channel 212, which is drawn in solid lines. In this embodiment the connection between loops is also performed inside condenser plate 208. The plate 208 and the plurality of fins 206 operate as a condenser. The heat sink may be fabricated from any suitable thermally conductive material, such as, without limitation, aluminum, copper, steel, and composite materials.

The evaporator plate 204 is sized and shaped to receive a heat generating component 226 at a heat receiving surface 222, such as a power electronic device. As a non-limiting example, the heat generating component 226 may be a power electronic device used in an inverter circuit to convert direct current (DC) electric power of a battery to alternating current (AC) electric power that drives an electric motor. Example power electronic devices include, but are not limited to insulated-gate bi-polar transistors (IGBT), power metal-oxide-semiconductor field-effect transistors (MOSFET), power transistors, power diodes, power silicon-coated rectifiers (SCR), Gallium nitride (GaN) and the like. In some embodiments, the power electronic devices may be fabricated from silicon carbide SiC.

The embodiments described herein may be a component of any type of electric or hybrid vehicle, such as an eVTOL, an automobile, a truck, a boat, and a plane. However, embodiments are not limited to vehicles. The embodiments described herein may be used in any application where it is desirable to remove heat from a heat generating component. Another non-limiting example includes a heat sink for central processing unit (CPU), a graphical processing unit (GPU), a server rack, a blockchain mining device, and the like.

The plurality of fins 206 extend from a cooling surface 224 of the evaporator plate 204. Any number of fins 206 may be utilized depending on the size and application of the heat sink 202. Although the fins 206 are illustrated as straight fins 206, the fins 206 may be take on other shapes and configurations.

The plurality of fins 206 extend through the condenser plate 208, which is offset from the cooling surface 224 of the evaporator plate 204 such that a gap 210 is present between the evaporator plate 204 and the condenser plate 208. Thus, the condenser plate 208 is disposed through the plurality of fins 206. The plurality of fins 206 extend beyond a top surface of the condenser plate 208. The condenser plate 208 is transverse to the plurality of fins 206. In the illustrated embodiment, the condenser plate 208 is in a plane parallel to the evaporator plate 204 and orthogonal to a plate defined by the plurality of fins 206. However, in other embodiments, the condenser plate 208 is a plane that is non-parallel to a plane of the evaporator plate 204 and/or non-orthogonal to a plane of the plurality of fins 206. In some embodiments, the condenser plate 208 is located at a mid-length of the plurality of fins to maximize thermal performance. It should be understood that the number, thickness and orientation of the plurality of fins 206 may be optimized in combination with the minimum number of loops.

As stated above and illustrated in FIG. 2, the PHP channel 212 is disposed within the evaporator plate 204, the plurality of fins 206 and the condenser plate 208. The PHP channel 212 is a closed-loop hollow channel that is filled with a working fluid having liquid slugs and vapor plugs. In some embodiments, the heat sink 202 is fabricated by an additive manufacturing process, such as three-dimensional printing. In this way, the PHP channel 212 may be formed within the thermally conductive material of the heat sink 202.

The PHP channel 212 has a plurality of evaporator passes 214 within the evaporator plate 204. The evaporator passes 214 provide area for the working fluid within the PHP channel 212 to receive heat from the heat generating component at the heat receiving surface 222, thereby warming the working fluid. Thus, the evaporator plate 204 acts in a similar manner as the evaporator section 106 shown in FIG. 1.

Each fin 206 has at least one fin pass 218 that extends from an individual evaporator pass 214. The fin passes 218 are disposed within individual fins 206 of the plurality of fins 206. It should be understood that each fin may have one or more fin passes 218.

The condenser plate 208 provides area for the PHP channel 212 to turn as condenser pass 216 to route the pin fin passes 218 between the evaporator pass 214 and the condenser plate 208. The condenser plate 208, along with the plurality of fins, therefore act as a condenser in a similar manner as the condenser sections 104 shown in FIG. 1.

Moving from the bottom left corner of the PHP channel 212, the PHP channel 212 moves up a left-most fin in a first fin pass 218, moves across the condenser plate 208 in a first condenser pass 216, moves to the right along the condenser plate 208 and then down a second, middle fin in a second fin pass 218. The PHP channel 212 continues along the evaporator plate 204 in a middle evaporator pass 214, up the second, middle fin 206 in a third fin pass 218 and across the condenser plate 208 in a second condenser pass 216. The PHP channel 212 then turns right across the condenser plate 208, travels down the third fin in a fourth fin pass 218, travels across the evaporator plate 204 in a third evaporator pass 214, and then up the third fin 206 in a fifth fin pass 218. Next, the PHP channel 212 travels across the condenser plate 208 in a third condenser pass 216, travels down the third fin 206 in a sixth fin pass 218, travels across the evaporator plate 204 in a return pass 220, and finally through a first evaporator pass 214 in the evaporator plate 204 to return to the start of the closed-loop PHP channel 212. The return pass 220 is a feature of the embodiment that increases the PHP performances but it can be omitted due to design constraints or cost constraints.

It is noted that although FIG. 2 illustrates the condenser plate as a solid block, in other embodiments the condenser plate 208 only has material proximate the condenser passes 216 within it.

During operation, the working fluid receives and absorbs heat from the heat generating component 226. The liquid slugs and vapor plugs pulsate back and forth or circulate in one direction, which transfers the liquid slugs from the evaporator plate 204 to the condenser plate 208. The condenser plate 208 is cooled by the presence of the plurality of fins 206 and the air passing by the plurality of fins 206. For example, airflow generated by a propeller of an aircraft may be forced through the plurality of fins 206, which removes heat from the plurality of fins 206 and therefore the working fluid within the condenser passes 216 of the condenser plate 208. The cooling of the working fluid in the condenser plate 208 and the heating of the working fluid in the evaporator plate 204 causes the liquid slugs and the vapor plugs to pulsate back and forth to remove heat from the heat generating component 226.

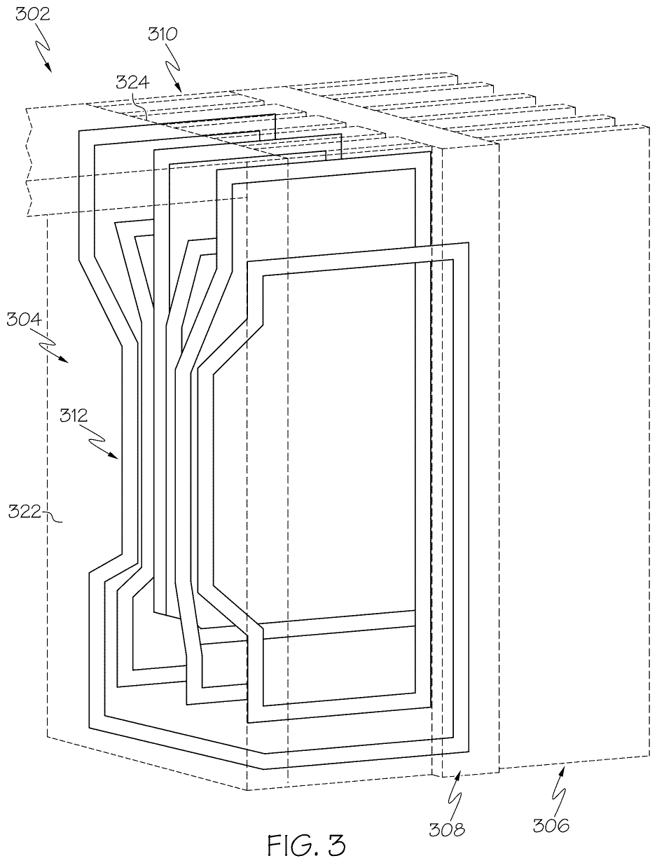

Referring now to FIG. 3, another example heat sink 302 is illustrated. The heat sink includes an evaporator plate 304, a plurality of fins 306, and a condenser plate 308. The evaporator plate 304 has a heat receiving surface 322 that is operable to receive a heat generating component (not shown in FIG. 3) and a cooling surface 324 from which the plurality of fins 306 extend. The condenser plate 308 is provided through the plurality of fins 306 such that a gap 310 is present between evaporator plate 304 and the condenser plate 308. A single closed-loop PHP channel 312 is routed throughout the evaporator plate 304, the plurality of fins 306, and the condenser plate 308. In this embodiment the connection between loops is mainly performed inside the evaporator plate 304. Like the heat sink 202 shown in FIG. 2, the heat sink 302 is fabricated using a thermally conductive material, such as aluminum, copper, steel or thermally conductive composite materials. The heat sink 302 may be fabricated by an additive manufacturing process, for example.

The example heat sink 302 has an array of six fins 306, as compared to the three fins 206 of the heat sink 202 shown in FIG. 2. However, any number of fins may be provided in any fin configuration. The number, thickness and orientation of the fins are regarding both air exchanger thermal resistance and pressure drops and PHP minimum number of loops.

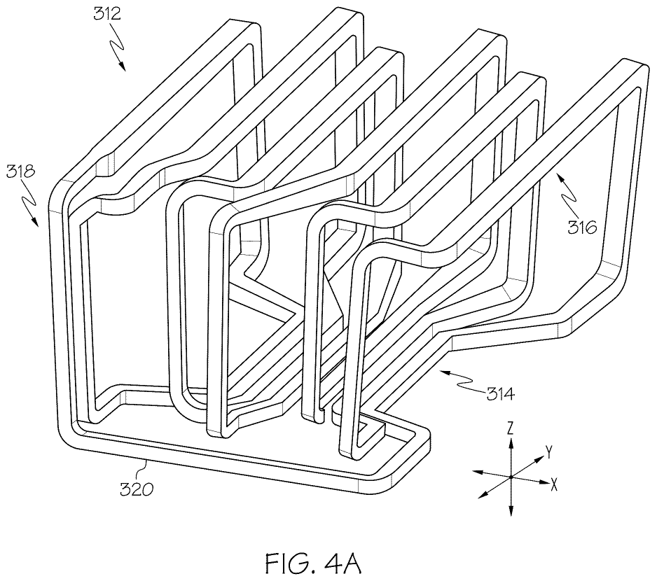

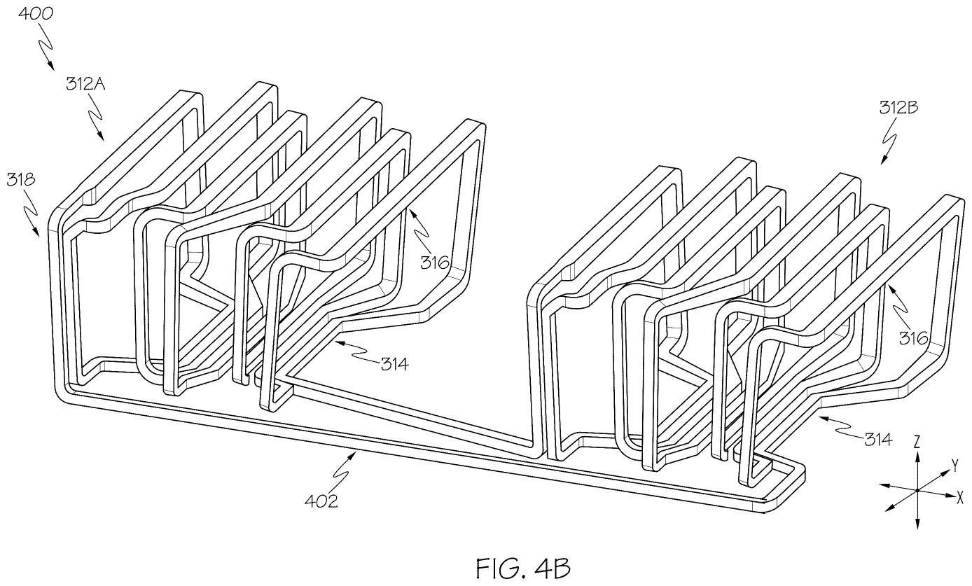

FIG. 4A illustrates the PHP channel 312 of FIG. 3 in isolation. The PHP channel 312 has a plurality of evaporator passes 314 within the evaporator plate 304, a plurality of fin passes 318 within the plurality of fins 306, and a plurality of condenser passes 316 within the condenser plate 308. The outermost fin passes are fluidly coupled by a return pass 320. Some of the fin passes 318 may be angled with respect to a system vertical Z-axis and some of the evaporator passes 314 and the condenser passes 316 may fan out such that a distance between adjacent evaporator passes 314 is smaller than a distance between adjacent condenser passes 316. For example, it may be desirably to closely locate the evaporator passes 314 so that they directly align with the heat generating component in the system vertical Z-axis direction. In this way, a maximum amount of heat flux may be transferred to the working fluid within the evaporator passes 314. In embodiments, a total fin surface area of the plurality of fins is at least twice as large as an evaporate plate surface area of the evaporator plate.

Further, separating the condenser passes 316 by as much as possible increases the surface area through which the PHP channel 312 travels, thereby increasing the surface area of cooling to remove heat. As shown in FIG. 4, the outermost fin passes 318 may be angled by a greater amount than the innermost fin passes. Additionally, the outermost evaporator passes 314 are fanned out to increase the distance between the condenser passes 316 as compared with the distance between the evaporator passes 314.

The heat sinks described herein can be operated at any orientation. There is minimal change in global thermal resistance between the evaporator plate and the fins at different orientation angles. Such a characteristic makes the heat sinks of the present disclosure ideal for aircraft, such as eVTOLs.

The array of fins and the array of fin passes may be designed to remove heat from multiple hot spots. FIG. 4B shows an array of PHP channels 400 defined by a first array of PHP channels 312A for cooling a first hot spot and a second array of PHP channels 312B for cooling a second hot spot. The first array of PHP channels 312A and the second array of PHP channels 312B are configured in the same way as the array of PHP channels 312 illustrated in FIG. 4A. The first array of PHP channels 312A and the second array of PHP channels 312B are fluidly coupled together by two return passes 402. It should be understood that any number of arrays of PHP channels may be provided in different configurations and arrangements.

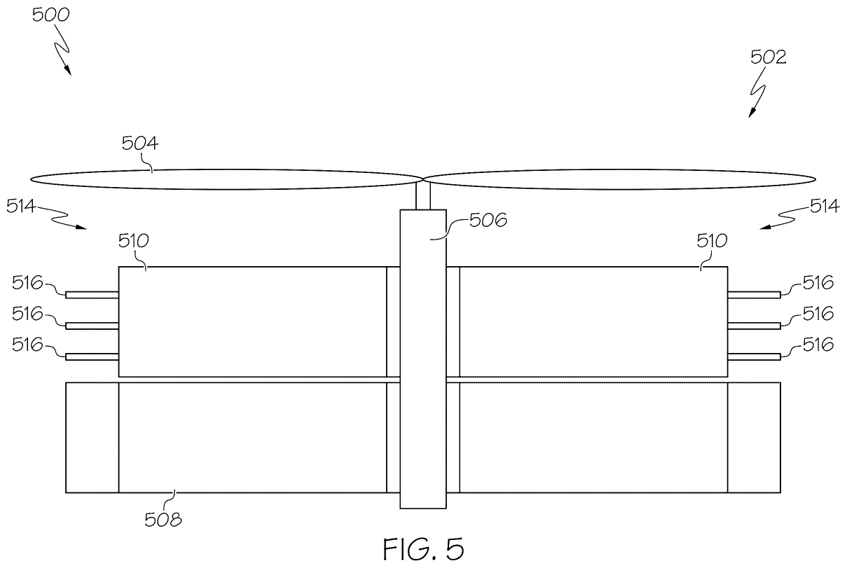

FIG. 5 illustrates an example propeller assembly 502 of an example eVTOL. The propeller assembly 502 generally includes an electric motor 508 that spins a shaft 506 to rotate a propeller 504 that generates lift for the eVTOL 500 so that it may become airborne. The propeller assembly 502 further includes a housing 510 that maintains electronic components (not shown) within an interior that control the operation of the electric motor 508. As a non-limiting example, the electric electronic components may be power electronic devices of an inverter circuit that switch the DC electric power of a batter into AC electric power for spinning the shaft 506 and controlling the eVTOL.

The electronic components 518 are thermally coupled to heat sinks 514 as described in the present disclosure. An electronic component 518 and heat sink 514 are collectively referred to herein as an “electronic assembly.” Each heat sink 514 includes an embedded closed-loop PHP channel having a working fluid therein. The PHP channel is routed through an evaporator plate, a plurality of fins and a condenser plate, as described above and illustrated in FIGS. 2-4. Heat flux generated by the electric electronic components 518 is transferred to the working fluid, thereby heating it up. The vapor plugs and liquid slugs of the working fluid pulsate in the PHP channel, which transfers heat from the evaporator plate to the condenser plate within the fins 516. Airflow generated by the propeller 504 passes through the fins 516, which removes the heat flux into the environment.

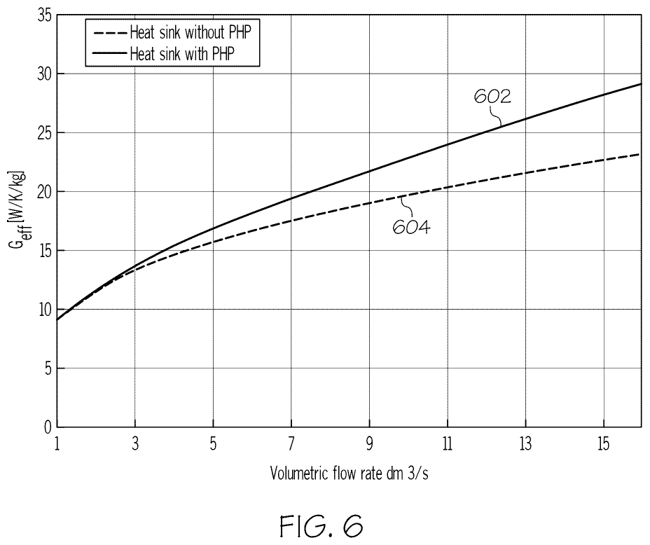

FIG. 6 is a graph that shows the comparison of heat sinks with (curve 602) and without (curve 604) a PHP channel with a heat input of 100 W. The thermal conductance per unit mass, G_{eff}, is derived by dividing the overall thermal conductance between the evaporator to the environmental air by the mass of each heat sink. The conductance was calculated by an empirical model based on test results. The horizontal axis of the graph is the volumetric flow rate [dm³/s] of airflow passing over the heat sinks. The heat sink with a PHP channel (curve 604) showed a typical 0-20% improvement compared to the heat sink without a PHP channel (curve 602).

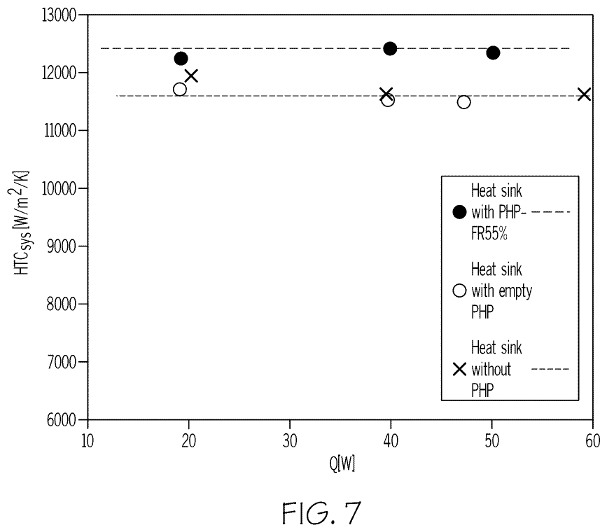

FIG. 7 plots the heat transfer coefficient from the evaporator plate to inlet air (i.e., the environmental air) (HTC_{sys}) versus heat input Q in watts for 1) a heat sink with a PHP channel filled with a working fluid at the filling ratio (FR) of 55%, 2) a heat sink with an empty PHP channel, and 3) a heat sink without a PHP channel. FIG. 7 shows that the heat sink with the filled PHP channel has a better heat transfer coefficient HTC_{sys} compared to that of the heat sink without a PHP channel.

Not only does a heat sink with a PHP channel have better thermal performance, it also has a reduced mass compared with a similar heat sink without a PHP channel due to the material void of the PHP channel. This reduction of mass and weight may be important in aircraft applications, for example.

It should now be understood that embodiments of the present disclosure are directed to heat sinks having a single closed-loop PHP channel that serves multiple fins. The heat sinks of the present disclosure have an evaporator plate coupled to a heat generating component, a plurality of fins, and a condenser plate through the plurality of fins. The closed-loop PHP channel has a plurality of evaporator passes within the evaporator plate, a plurality of fin passes through the plurality of fins, and a plurality of condenser passes through the condenser plate. A working fluid having liquid slugs and vapor plugs within the PHP channel evaporates and condenses within the heat sink. Heat is transferred between the evaporator plate and the condenser plate by the pulsating liquid slugs and vapor plugs within the PHP channel.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

1. A heat sink comprising:
an evaporator plate comprising a heat receiving surface and a cooling surface;
a plurality of fins extending from the heat receiving surface;
a condenser plate transverse from the plurality of fins such that a gap is defined between the evaporator plate and the condenser plate; and
a pulsating heat pipe channel embedded within the evaporator plate, the plurality of fins, and the condenser plate.

2. The heat sink of claim 1, wherein a total fin surface area of the plurality of fins is at least twice as large as an evaporate plate surface area of the evaporator plate.

3. The heat sink of claim 1, wherein the pulsating heat pipe channel comprises a plurality of evaporator passes within the evaporator plate, a first pass and a second pass within each fin of the plurality of fins, and a plurality of condenser passes within the condenser plate.

4. The heat sink of claim 3, wherein the pulsating heat pipe channel is routed such that it traverses from an individual evaporator pass of the plurality of evaporator passes to the first pass of a first fin of the plurality of fins, from the first pass to an individual condenser pass of the plurality of condenser passes, from the individual condenser pass to the second pass of the first fin, from the second pass of the first fin to another evaporator pass of the plurality of evaporator passes.

5. The heat sink of claim 3, wherein the pulsating heat pipe channel further comprises a return pass within the evaporator plate.

6. The heat sink of claim 1, wherein the pulsating heat pipe channel is filled with a fluid comprising a plurality of liquid slugs and a plurality of vapor plugs.

7. The heat sink of claim 1, wherein the heat receiving surface is configured to receive a heat generating component.

8. An electronic assembly comprising:
an electronic device; and
a heat sink comprising:
an evaporator plate comprising a heat receiving surface and a cooling surface, wherein the electronic device is coupled to the heat receiving surface;
a plurality of fins extending from the heat receiving surface;
a condenser plate transverse from the plurality of fins such that a gap is defined between the evaporator plate and the condenser plate; and
a pulsating heat pipe channel embedded within the evaporator plate, the plurality of fins, and the condenser plate.

9. The electronic assembly of claim 8, wherein a total fin surface area of the plurality of fins is at least twice as large as an evaporate plate surface area of the evaporator plate.

10. The electronic assembly of claim 8, wherein the pulsating heat pipe channel comprises a plurality of evaporator passes within the evaporator plate, a first pass and a second pass within each fin of the plurality of fins, and a plurality of condenser passes within the condenser plate.

11. The electronic assembly of claim 10, wherein the pulsating heat pipe channel is routed such that it traverses from an individual evaporator pass of the plurality of evaporator passes to the first pass of a first fin of the plurality of fins, from the first pass to an individual condenser pass of the plurality of condenser passes, from the individual condenser pass to the second pass of the first fin, from the second pass of the first pin to another evaporator pass of the plurality of evaporator passes.

12. The electronic assembly of claim 10, wherein the pulsating heat pipe channel further comprises a return pass within the evaporator plate.

13. The electronic assembly of claim 8, wherein the pulsating heat pipe channel is filled with a fluid comprising a plurality of liquid slugs and a plurality of vapor plugs.

14. An electric vertical take-off and landing vehicle (eVTOL) comprising:
a body;
a propeller coupled to the body;
an electric motor operable to rotate the propeller;
an electronic device operable to control the electric motor; and
a heat sink comprising:
an evaporator plate comprising a heat receiving surface and a cooling surface, wherein the electronic device is coupled to the heat receiving surface;
a plurality of fins extending from the heat receiving surface;
a condenser plate transverse from the plurality of fins such that a gap is defined between the evaporator plate and the condenser plate; and
a pulsating heat pipe channel embedded within the evaporator plate, the plurality of fins, and the condenser plate.

15. The eVTOL of claim 14, wherein a total fin surface area of the plurality of fins is at least twice as large as an evaporate plate surface area of the evaporator plate.

16. The eVTOL of claim 14, wherein the pulsating heat pipe channel comprises a plurality of evaporator passes within the evaporator plate, a first pass and a second pass within each fin of the plurality of fins, and a plurality of condenser passes within the condenser plate.

17. The eVTOL of claim 16, wherein the pulsating heat pipe channel is routed such that it traverses from an individual evaporator pass of the plurality of evaporator passes to the first pass of a first fin of the plurality of fins, from the first pass to an individual condenser pass of the plurality of condenser passes, from the individual condenser pass to the second pass of the first fin, from the second pass of the first pin to another evaporator pass of the plurality of evaporator passes.

18. The eVTOL of claim 16, wherein the pulsating heat pipe channel further comprises a return pass within the evaporator plate.

19. The eVTOL of claim 14, wherein the pulsating heat pipe channel is filled with a fluid comprising a plurality of liquid slugs and a plurality of vapor plugs.

20. The eVTOL of claim 14, wherein plurality of fins extend beyond a surface of the body.
